(19) United States
(12) Patent Application Publication
(10) Pub. No.: US 2007/0177745 A1
(43) Pub. Date: Aug. 2, 2007

(54) Tube amp simulator

(76) Inventor: Robert M. Kunstadt, New York, NY (US)

Correspondence Address: Robert Kunstadt, 14th Floor, 729 Seventh Avenue, New York, NY, 10019, US

(21) Appl. No.: 11/345,770

(22) Filed: Feb. 2, 2006

(51) Int. Cl. H03F 21/00; G10H 1/00

(52) U.S. Cl. 381/120; 381/118

(57) ABSTRACT

The following components are connected in parallel: a capacitor, a resistor and a diode. In a typical application, to one end of the combination one may connect the signal from an electric guitar's pickup. The other end of the combination is connected to the input of a guitar amp, generally a transistor (solid-state) amp which it is desired to make sound like a tube amp.

### FIELD OF THE INVENTION

This invention relates to the field of circuit modifications and accessories for use with audio amplifiers, in particular those for electric musical instruments such as electric guitar.

### PRIOR ART

It is highly desirable to play an electric guitar through a tube amplifier, due to the characteristic tube tone that results. Transistorized amplifiers sound cold and sterile in comparison, in the opinion of many players. However, a tube amp is heavy, expensive and fragile, so there are disadvantages to using one. Hence many attempts have been made to simulate a tube amp with a solid-state device, such as the “fuzz box”. Such devices simulate tube amps to a degree, but they also introduce annoying artifacts into the guitar tone, such as buzzing. Hence, there is a long-felt need for a simple, inexpensive and realistic way to simulate a tube amp with a solid-state device.

### SUMMARY OF THE INVENTION

The invention meets that need with a novel combination of elements: a capacitor, a resistor and a diode connected to each other in parallel and inserted within the signal chain. In accordance with the invention, the following components are connected in parallel: a capacitor, a resistor and a diode. To one end of the combination, one may connect the signal from an electric guitar's pickup. The other end of the combination is connected to the input of a guitar amp, generally a transistor (solid-state) amp which it is desired to make sound like a tube amp.

### DESCRIPTION OF THE DRAWINGS

FIG. 1 is a schematic of typical components employed in a circuit according to the invention.

### DETAILED DESCRIPTION OF THE INVENTION

### EXAMPLE 1

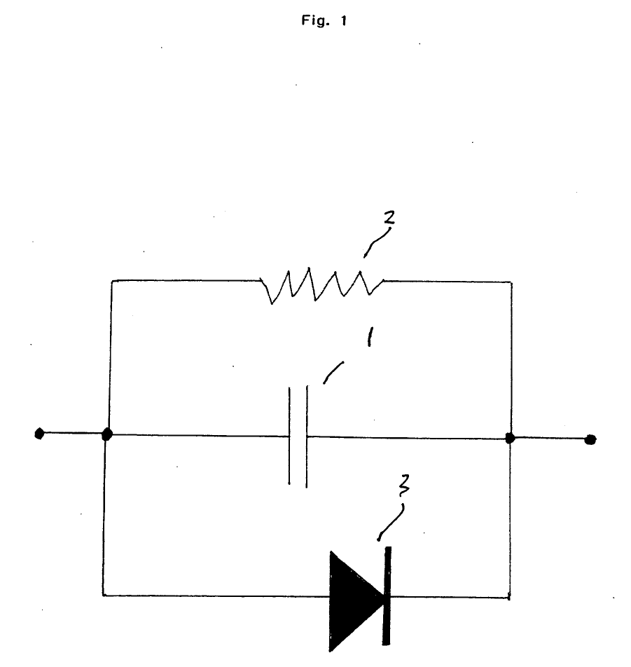

Connect the signal cable from an electric guitar (e.g., BORN TO ROCK Model F4c guitar having two KENT ARMSTRONG rails humbucking pickups) to a mono phone jack. To the signal terminal of the jack, connect in parallel a .001 uF capacitor 1, a 2.2M resistor 2, and a 1N4003 diode 3 (see FIG. 1). Diode polarity is not significant; it may be reversed from that shown; moreover, it should be understood that a “diode” is a means capable in principle of differentiating current flows directionally.

Attach the other ends of the aforesaid components 1, 2 and 3 to the signal terminal of another mono phone jack. Connect the ground terminals of the two jacks, to each other. Connect a signal cable from the second jack, to the input jack of a guitar amp, such as a MARSHALL Valvestate 8080. Use the “clean” channel of that amp, which has a solid-state signal path (no tubes). Play the guitar and listen. Instead of the typical modern MARSHALL clean-channel tone produced by the stock 8080 model, the tone is modified to resemble a highly-desirable tube amp tone, such as that of the “blackface” FENDER Twin Reverb model amp of the 1960's.

This embodiment may be realized within the housing of a “stomp-box” footpedal, optionally equipped with a bypass switch and/or adjustable controls for the component values. For example, the value of the resistor in the three-part combination may range from about 220 k, to 2.2 M or more.

### EXAMPLE 2

In another embodiment of the invention, the foregoing three-part combination is inserted within the feedback loop of a solid-state IC amp, such as one using National Semiconductor's LM3886. It is inserted in parallel with the standard manufacturer-recommended feedback circuit resistor. The effect of the inserted combination of the invention may be limited as desired, by placing a resistor in series with the combination to reduce its effect in the feedback loop. This embodiment may be used to permit an LM3886 IC to simulate the tone of a tube HiFi amp, such as the popular (and expensive) MACINTOSH tube amp; or a GRUNDIG tube console radio from the 1950's.

### EXAMPLE 3

The foregoing three-part combination is attached internally within a guitar amp, between the input jack of the guitar amp, and the pre-amp section thereof (which may be the input of an LM3886 IC). In this instance, the operation is similar to Example 1, except the combination is not removable by unplugging. It may, however, be provided with a bypass switch, including if desired a footpedal (or the like) for remote operation.

The invention is not limited to the embodiments described, but also includes such variations as would be apparent to one skilled in the art in view of the disclosure, including without limitation variations in the selected component values.

I claim:

1. A capacitor, a resistor and a diode connected to each other in parallel and inserted within the signal chain of a solid-state audio-frequency amplifier.

2. A capacitor, a resistor and a diode connected to each other in parallel and inserted within the feedback loop of a solid-state audio-frequency amplifier.

3. Means for simulating a tube amplifier by a solid-state audio-frequency amplifier circuit, said means comprising a first means for storing electricity, a second means for reducing the flow of electricity of any polarity, and a third means for modifying the flow of electricity of substantially only one polarity; said three means being connected to each other in parallel and adapted to modify the audio signal of said amplifier.
